(19) United States
(12) Patent Application Publication
(10) Pub. No.: US 2015/0255456 A1
(43) Pub. Date: Sep. 10, 2015

(54) REPLACEMENT FIN INSOLATION IN A SEMICONDUCTOR DEVICE

(71) Applicant: GLOBALFOUNDRIES Inc., Grand Cayman (KY)

(72) Inventors: Ajey Poovannummoottil Jacob, Albany, NY (US); Min-hwa Chi, Malta, NY (US)

(73) Assignee: GLOBALFOUNDRIES Inc., Grand Cayman (KY)

(21) Appl. No.: 14/195,884

(22) Filed: Mar. 4, 2014

(51) Int. Cl. H01L 27/088; H01L 29/161; H01L 21/266; H01L 21/8234; H01L 21/265; H01L 21/02; H01L 29/16; H01L 29/06

(52) U.S. Cl. CPC H01L 27/0886; H01L 29/16; H01L 29/161; H01L 29/0649; H01L 21/823431; H01L 21/823481; H01L 21/26506; H01L 21/02532; H01L 21/266

(57) ABSTRACT

Embodiments herein provide approaches for forming a set of replacement fins in a semiconductor device. Specifically, a device is formed having a set of replacement fins over a substrate, each of the set of replacement fins comprising a first section separated from a second section by a liner layer, the first section having a lower dopant centration than a dopant concentration of the second section. In one embodiment, sequential epitaxial deposition with insitu doping is used to form the second section, the liner layer, and then the first section of each of the set of replacement fins. In another embodiment, the second section is formed over the substrate, and the liner layer is formed through a carbon implant. The first section is then epitaxially formed over the liner layer, and serves as the fin channel. As provided, upward dopant diffusion is suppressed, resulting in the first section of each fin being maintained with low doping so that the fin channel is fully depleted channel during device operation.

### BACKGROUND

1. Technical Field

This invention relates generally to the field of semiconductors, and more particularly, to approaches for providing replacement fin isolation in a semiconductor device.

2. Related Art

A typical integrated circuit (IC) chip includes a stack of several levels or sequentially formed layers of shapes. Each layer is stacked or overlaid on a prior layer and patterned to form the shapes that define devices (e.g. complementary metal-oxide-semiconductor field effect transistors (C-MOSFET or CMOS) for devices with planar channel, and fin field effect transistors (FinFETs) for MOSFET with vertical fin-like structure as channel) and connect the devices into circuits. In a typical state of the art complementary insulated gate FINFET process, which is similar to the CMOS process, layers are formed on a wafer to form the devices on a surface of the wafer. Further, the surface may be the surface of a silicon layer on a silicon on insulator (SOI) wafer. A simple FinFET includes a gate stack layer perpendicular across and on top of a silicon island (i.e., fins) formed from the silicon surface layer. Each of these layers of shapes, also known as mask levels or layers, may be created or printed optically through well known photolithographic masking, developing and patterning steps, e.g., etching, implanting, deposition, etc., as known to those skilled in the field.

Silicon based FinFETs have been successfully fabricated using conventional C-MOSFET or CMOS technology. A typical FinFET is fabricated on a substrate with an overlying insulating layer with a thin ‘fin’ extending from the substrate, for example, etched into a silicon layer of the substrate. The channel of the FinFET is formed in this vertical fin. A single or double gate is usually provided over the fin(s). A double gate can be beneficial in that there is a gate on both sides of the channel, which can provide control of the channel from both sides. Further advantages of FinFETs include reducing the short channel effect and higher current flow. Other FinFET architectures may include three effective gates (tri-gate) wrapped-around the fins, which can allow superior gate control of the vertical channel from both the sides and tops of the fins.

In the prior art device 100 depicted by the cross-sectional view through the fin parallel to the fin direction of FIG. 1, conventional bulk FinFETs suffers from punch-through leakage near the bottom of the fin channel in-between the source and drain (S/D), which significantly contributes to overall device leakage. In one current art approach, a subsequently formed gate (not shown) wrapped-around the fin(s) can provide effective electrostatic control of the fin channel area to the depth of S/D. Another current art approach minimizes the source to drain (S/D) leakage by incorporating a punch-through stopper (PTS) implant (i.e. junction isolation) to increase the local doping of the fin in-between S/D below the active fin channel area. The fin channel (e.g., Si or SiGe) is effectively maintained un-doped (or low-doping) for higher carrier mobility by the wrap-around gate structure. However, there are at least three issues with the bulk-FinFET having conventional junction isolation by PTS implant. First, there is upward diffusion of the PTS implanted dopants into the fin channel area (e.g., by thermal cycles), and the fin channel area is difficult to keep at a low dopant level. The carrier mobility is also degraded as a result. Second, the S/D junction leakage is still significantly high as contributed by the junction leakage current between the highly doped S/D and the PTS implanted region. Third, fins are damaged during the PTS implant. While a subsequent anneal process (e.g., rapid thermal anneal) can remove the damage, it comes with a trade-off, i.e., upward diffusion of PTS dopants. Carrier mobility is further degraded.

### SUMMARY

In general, embodiments herein provide approaches for forming a set of replacement fins in a semiconductor device. Specifically, a device is formed having a set of replacement fins over a substrate, each of the set of replacement fins comprising a first section separated from a second section by a liner layer, the first section having a lower dopant centration than a dopant concentration of the second section. In one embodiment, sequential epitaxial deposition with insitu doping is used to form the second section, the liner layer, and then the first section of each of the set of replacement fins. In another embodiment, the second section is formed over the substrate, and the liner layer is formed through a carbon implant. The first section is then epitaxially formed over the liner layer. As provided, upward dopant diffusion is suppressed, resulting in the first section of each fin being maintained with low doping so that the fin channel is fully depleted channel during device operation.

One aspect of the present invention includes a semiconductor device comprising: a set of replacement fins formed over a substrate, each of the set of replacement fins comprising a first section and a second section, the first section having a lower dopant centration than a dopant concentration of the second section; and a liner layer between the first section from the second section.

Another aspect of the present invention includes a method for forming a semiconductor device, the method comprising: forming a set of replacement fins over a substrate, each of the set of replacement fins comprising a first section and a second section, the first section having a lower dopant centration than a dopant concentration of the second section; and forming a liner layer between the first section from the second section.

Another aspect of the present invention includes a method for forming a set of replacement fins in a semiconductor device, the method comprising: forming a set of replacement fins over a substrate, each of the set of replacement fins comprising a first section and a second section, the first section having a lower dopant centration than a dopant concentration of the second section; and forming a liner layer between the first section from the second section.

### BRIEF DESCRIPTION OF THE DRAWINGS

These and other features of this invention will be more readily understood from the following detailed description of the various aspects of the invention taken in conjunction with the accompanying drawings in which:

FIG. 1 shows a cross-sectional view of a prior art semiconductor device;

FIGS. 2(A)-2(H) show cross-sectional views of an approach for forming a set of replacement fins in a semiconductor device according to an illustrative embodiment; and

FIGS. 3(A)-3(F) show cross-sectional views of an approach for forming a set of replacement fins in a semiconductor device according to another illustrative embodiment.

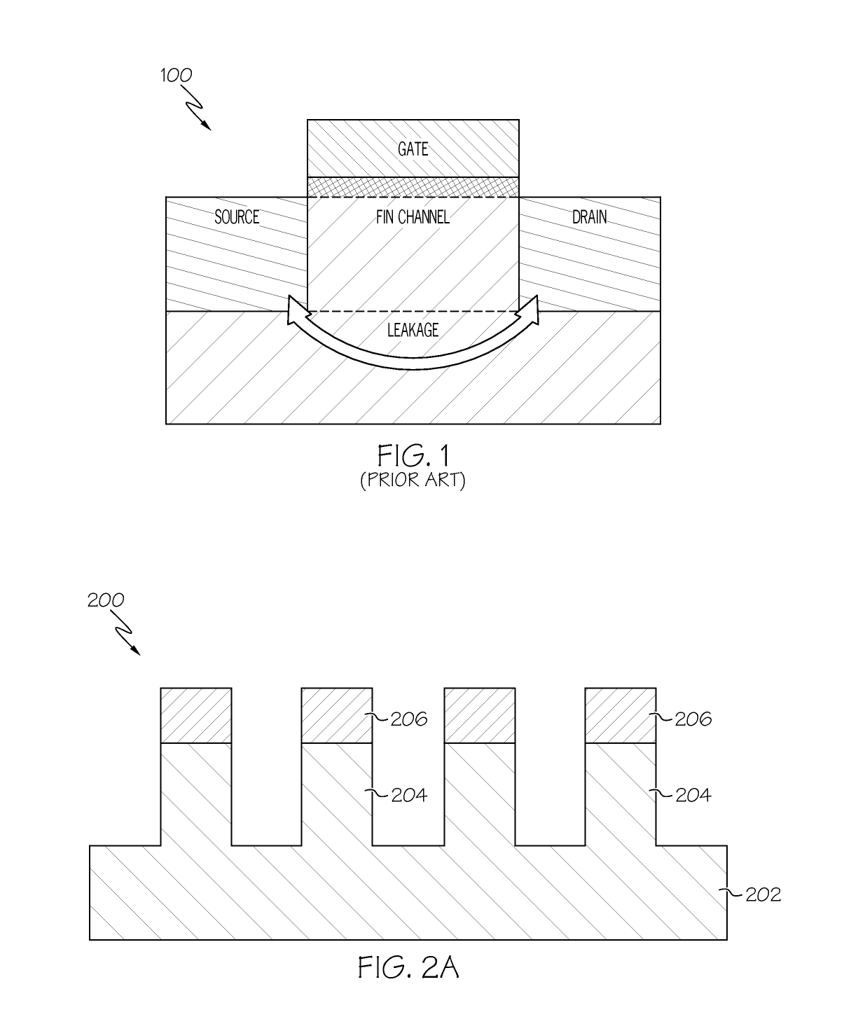

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines, which would otherwise be visible in a “true” cross-sectional view, for illustrative clarity. Furthermore, for clarity, some reference numbers may be omitted in certain drawings.

### DETAILED DESCRIPTION

Exemplary embodiments will now be described more fully herein with reference to the accompanying drawings, in which one or more approaches are shown. It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure, e.g., a first layer, is present on a second element, such as a second structure, e.g. a second layer, wherein intervening elements, such as an interface structure, e.g. interface layer, may be present between the first element and the second element.

As used herein, “depositing” may include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

As stated above, embodiments herein provide approaches for forming a set of replacement fins in a semiconductor device. Specifically, a device is formed having a set of replacement fins over a substrate, each of the set of replacement fins comprising a first section separated from a second section by a liner layer, the first section having a lower dopant centration than a dopant concentration of the second section. In one embodiment, sequential epitaxial deposition with insitu doping is used to form the second section, the liner layer, and then the first section of each of the set of replacement fins. In another embodiment, the second section is formed over the substrate, and the liner layer is formed through a carbon implant. The first section is then epitaxially formed over the liner layer, and serves as the fin channel. As provided, upward dopant diffusion is suppressed, resulting in the first section of each fin being maintained with low doping so that the fin channel is fully depleted channel during device operation.

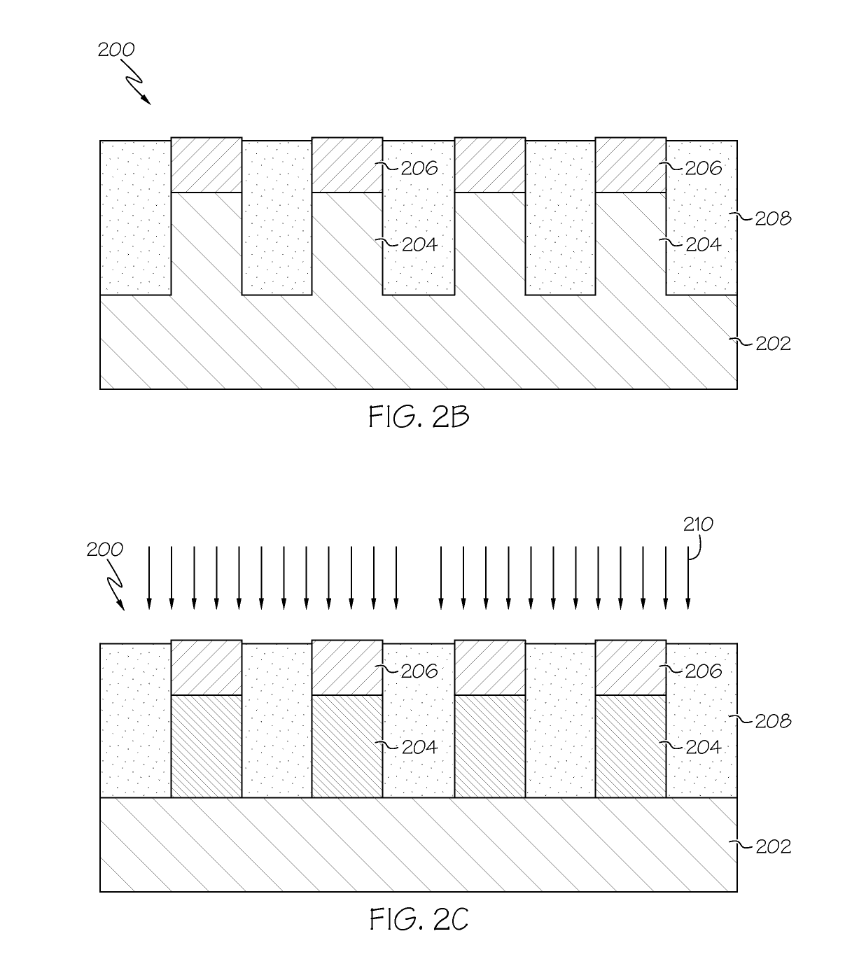

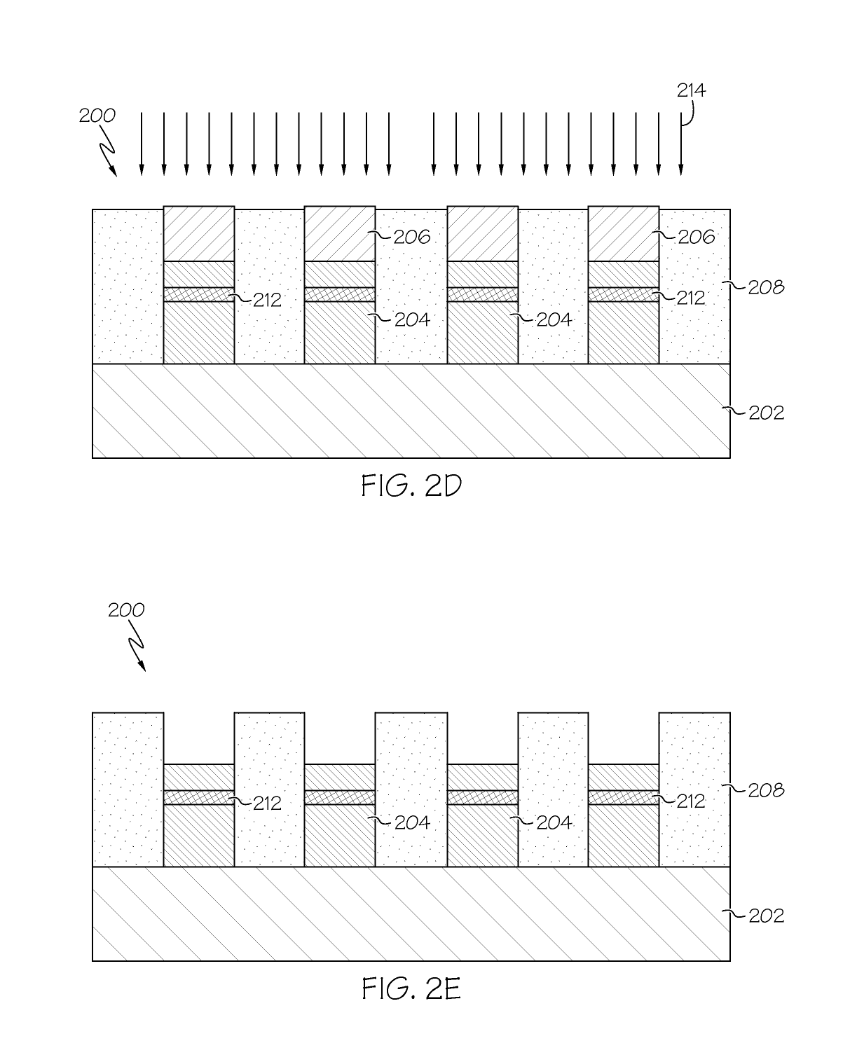

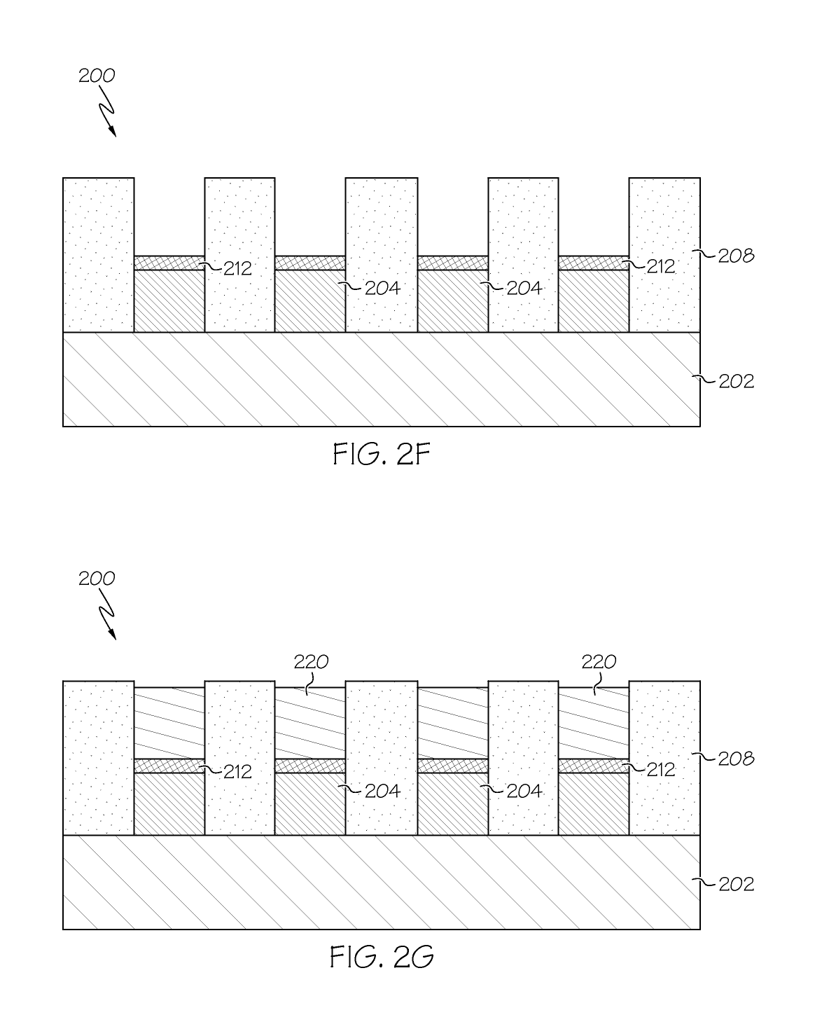

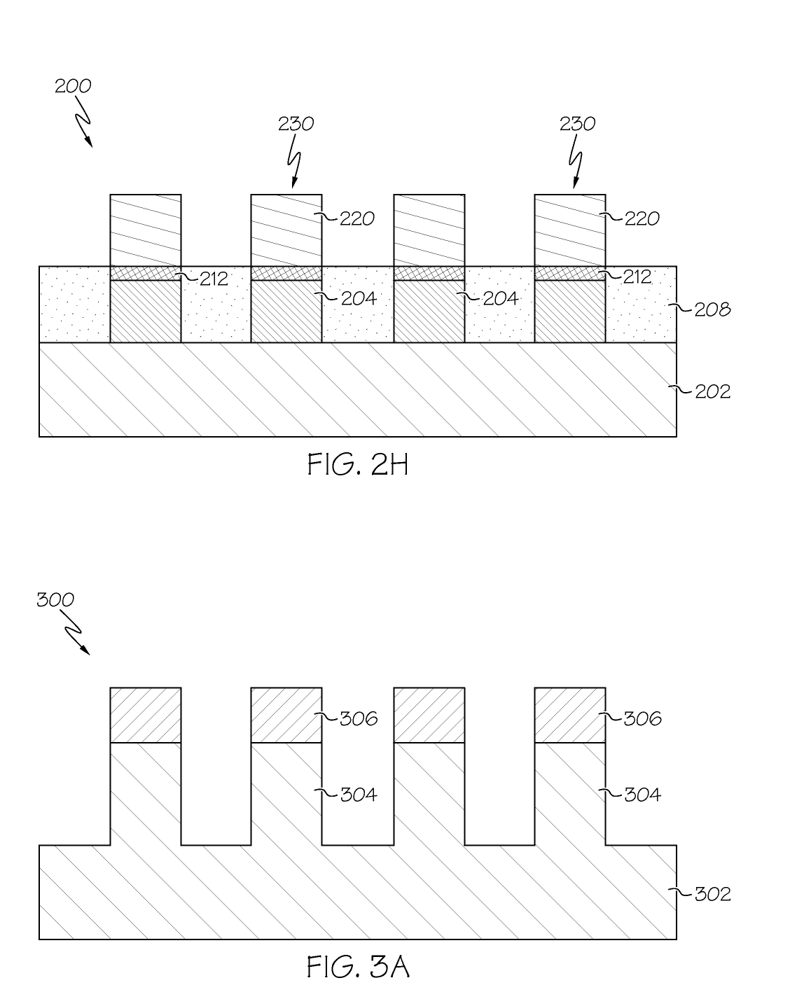

With reference again to the figures, FIG. 2(a) shows a cross sectional view of a device 200 according to an embodiment of the invention. Device 200 comprises a substrate 202 (or well) and plurality of fins 204 formed thereon. Device 200 further comprises a hard mask 206 (e.g., Si₃N₄) formed atop each of fins 204. In one embodiment, substrate 202 includes a bulk silicon substrate (e.g., wafer). Substrate 202 may be silicon on insulator (SOI).

In one embodiment, substrate 202 comprises a super-steep retrograde well (SSRW), and device 200 is field effect transistor (FET). A SSRW FET is a device geometry with an undoped channel and a heavily-doped laterally-uniform section that is expected to exhibit better short-channel control, better carrier transport properties, lower threshold voltage variations, and lower parasitic series resistance than conventional halo-doped devices on either SOI or bulk Si substrate. For the SSRW FET, the presence of a heavily doped section leads to significantly improved short channel effects (SCEs) as compared to conventional halo-doped devices. In the SSRW FET, there is no need for halo doping as the heavily doped section fulfills the function of controlling SCEs and avoids the above-identified halo doping problems.

Fins 204 may be fabricated using any suitable process including one or more photolithography and etch processes. The photolithography process may include forming a photoresist layer (not shown) overlying substrate 202 (e.g., on a silicon layer) with hard mask 206 coated on top, then exposing the resist to a pattern, performing post-exposure bake processes, and developing the resist to form a masking element including the resist (i.e. the “soft” hard mask). The resist masking element may then be used to etch (or pattern) the masking material of hard mask 206. After removal of the photo resist, hard mask 206 is used to etch fins 204 into the silicon layer on the substrate 202, e.g., using reactive ion etch (RIE) and/or other suitable processes.

In one embodiment, fins 204 with small dimension (e.g., <20 nm) and pitches (<90 nm) are formed by a double-patterning lithography (DPL) process. DPL is a method of constructing a pattern on a substrate by dividing the pattern into two interleaved patterns. DPL allows enhanced feature (e.g., fin) density. Various DPL methodologies may used including, double exposure (e.g., using two mask sets), forming spacers adjacent features and removing the features to provide a pattern of spacers, resist freezing, and/or other suitable processes.

Next, as shown in FIG. 2(B), an oxide material 208 is deposited over device 200, followed by chemical-mechanical-polish (CMP) step for planarization, wherein hard mask 206 serves as the CMP stop. Then, an ion implantation 210 to fins 204 is performed to form heavily doped areas (referred to as wells) in the silicon of fins 204, as shown in FIG. 2(C). In one embodiment, ion implantation 210 may be performed on selective areas by masking steps (i.e., photolithography, ion implantation, and photoresist (PR) stripping processes). Photolithography is used for selectively defining NFET or PFET areas for well implants. NFET well ion implantation involves a p-type implant species such as B, BF₂, or In, while PFET well ion implantation involves an n-type implant species such as As, P, or Sb.

Next, as shown in FIG. 2(D), a liner layer 212 is formed within each fin 204 using a carbon implant 214 and drive-in process, and oxide material 208 is recessed selective to hard mask 206 via CMP, as shown in FIG. 2(E). Hard mask 206 is then removed by a suitable etching process, e.g., a wet etch for selectively removing silicon nitride (Si₃N₄) using hot (approximately 145-180° C.) aqueous phosphoric acid (H₃PO₄) solutions (often referred to as hot phos), as shown in FIG. 2(F).

As shown in FIG. 2(F), fins 204 are then removed above liner layer 212 by Si etching (e.g., selective to C-doped liner layer 212). In one embodiment, fins 204 above liner layer 212 are removed using a Si RIE process. In another embodiment, an isotropic hydrogen chloride (HCl) vapor etch (MNF09) is performed, which is highly selective to oxide.

Next, as shown in FIG. 2(G), a high mobility channel material 220 (e.g., Si, Si—Ge, or other III-V material) is epitaxially grown over liner layer 212, e.g., up to the same level as the surface of oxide material 208. In this embodiment, high mobility channel material 220 comprises Si or Si—Ge or III-V materials and is formed by selective epi growth (SEG) methods with low-doping. This portion of fins 204 with high mobility channel materials 220 (i.e., above the liner layer 212) serves as the active channel of device 200.

Oxide material 208 is then recessed (e.g., by dry or wet process), as shown in FIG. 2(H) to reveal the active fins, i.e., high mobility channel material 220. Oxide material 208 is recessed down to the level of liner layer 212 so that a subsequently formed gate (not shown) will fully wrap around the active fin portion.

As shown, device 200 of FIG. 2(H) includes a set of replacement fins 230 formed over substrate 202, each of set of replacement fins 230 comprising a first section (i.e., high mobility channel material 220) and a second section (i.e., heavily doped portion of fins 204 below liner layer 212). In an exemplary embodiment, the first section (i.e., upper portion) of each fin 204 has a lower dopant centration (or no dopant) than the high dopant concentration of the second section (i.e., bottom portion). The second section is more heavily doped to serve as a punch-through stopper, while liner layer 212 prevents upward dopant diffusion, resulting in a fully depleted channel during operation.

Although not shown, it will be appreciated that a set of gate stack structures may be formed atop device 200. In one embodiment, the gate stack structure includes a gate dielectric layer and a metal gate electrode stack. Numerous other layers may also be present, for example, capping layers, interface layers, spacer elements, and/or other suitable features. The gate dielectric layer may include dielectric material such as, silicon oxide, silicon nitride, silicon oxynitride, dielectric with a high dielectric constant (high k), and/or combinations thereof. Examples of high k materials include hafnium silicate, hafnium oxide, zirconium oxide, aluminum oxide, hafnium dioxide-alumina (HfO₂—Al₂O₃) alloy, and/or combinations thereof. The gate dielectric layer may be formed using processes such as, photolithography patterning, oxidation, deposition, etching, and/or other suitable processes. The gate electrode may include polysilicon, silicon-germanium, a metal including metal compounds such as, Mo, Cu, W, Ti, Ta, TiN, TaN, NiSi, CoSi, and/or other suitable conductive materials known in the art. The gate electrode may be formed using processes such as, physical vapor deposition (PVD), CVD, plasma-enhanced chemical vapor deposition (PECVD), atmospheric pressure chemical vapor deposition (APCVD), low-pressure CVD (LPCVD), high density plasma CVD (HD CVD), atomic layer CVD (ALCVD), and/or other suitable processes which may be followed, for example, by photolithography and/or etching processes. In one embodiment, the gate structure comprises a replacement (i.e., dummy) metal gate (RMG), which may be formed using any now known or later developed techniques, e.g., material deposition, mask material deposition, patterning, etching, etc., to form the RMG structure.

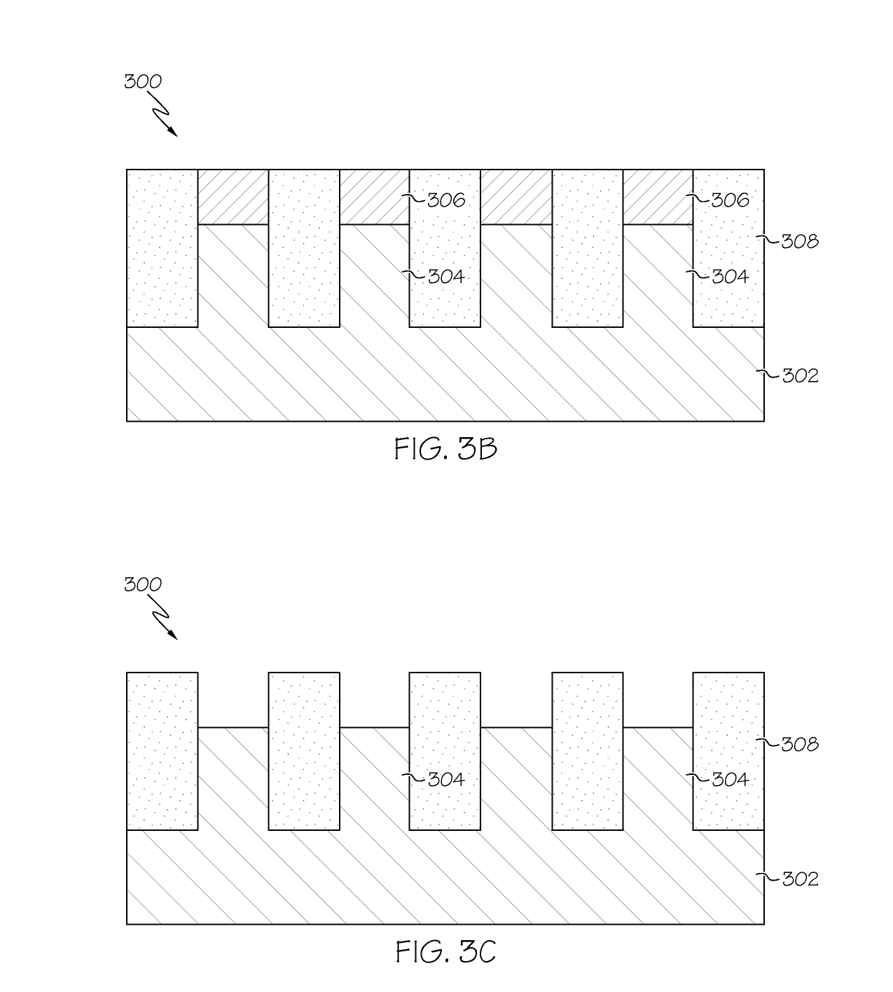

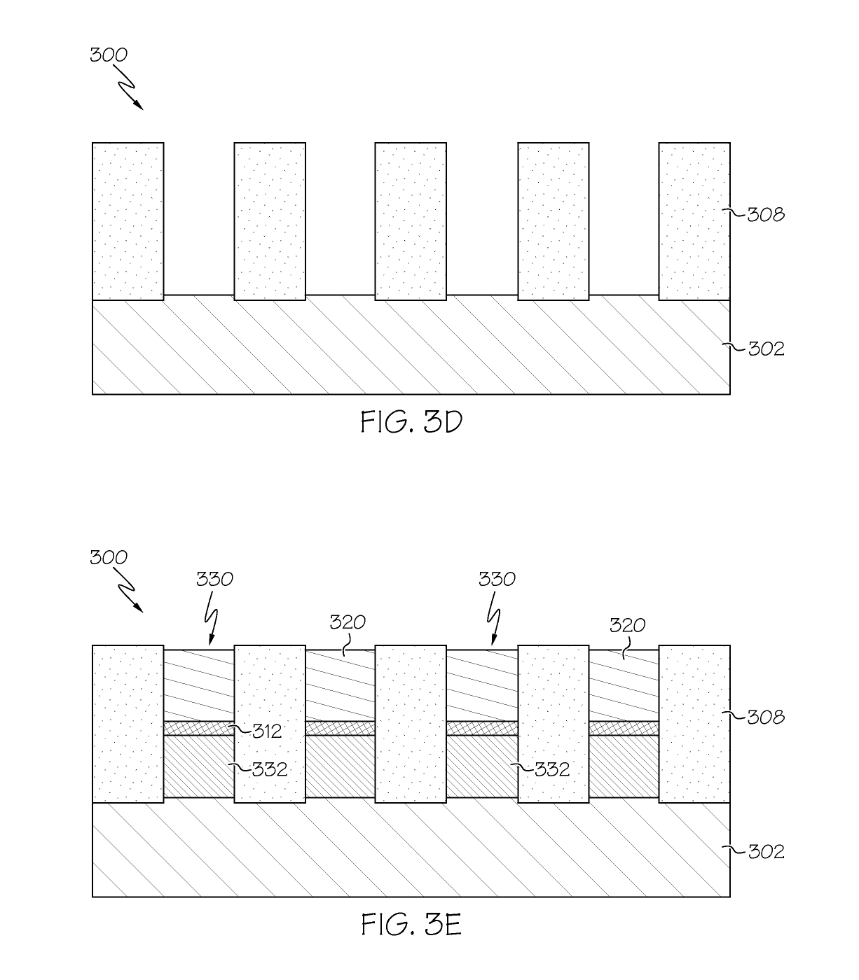

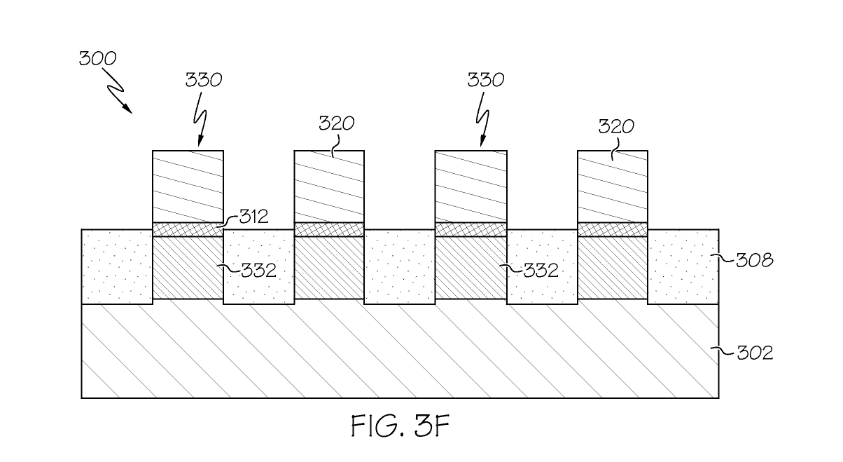

Turning now to FIGS. 3(A)-3(F), another embodiment for forming a set of replacement fins in a semiconductor device is shown. FIG. 3(a) shows a cross sectional view of a device 300 including a substrate 302 and plurality of fins 304 formed thereon. Device 300 further comprises a hard mask 306 (e.g., Si₃N₄) formed atop each of fins 304. In one embodiment, substrate 302 includes a silicon substrate (e.g., wafer). Substrate 302 may be silicon in a crystalline structure (e.g., a bulk silicon substrate). In one embodiment, substrate 302 comprises a super-steep retrograde well (SSRW), and device 300 is a fin-field effect transistor (FinFET).

Next, an oxide material 308 is deposited over device 300 and removed via CMP selective to hard mask 306, as shown in FIG. 3(B). Hard mask 306 is then removed (e.g., by selective wet, hot Phosphoric acid), as shown in FIG. 3(C), followed by removal of fins 304, as shown in FIG. 3(D). In one embodiment, fins 304 are removed using a Si RIE process. In another embodiment, an isotropic hydrogen chloride (HCl) vapor etch (MNF09) is performed, which is highly selective to oxide.

As shown in FIG. 3(E), sequential epitaxial deposition with insitu doping is used to form the second section, the liner layer, and then the first section of each of a set of replacement fins 330. As shown, device 300 includes set of replacement fins 330 formed over substrate 302, each of set of replacement fins 330 comprising a first section (i.e., high mobility channel material 320) and a second section 332 (i.e., heavily doped portion of fins below liner layer 312). In an exemplary embodiment, first section 320 of each fin 330 has a lower dopant centration (or no dopant) than the high dopant concentration of second section 332. Second section 332 is more heavily doped to serve as a punch-through stopper, while liner layer 312 prevents upward dopant diffusion, resulting in a fully depleted channel during operation.

Oxide material 308 is then recessed (e.g., by dry or wet process), as shown in FIG. 3(F) to reveal the active fins, i.e., high mobility channel material 320. Oxide material 308 is recessed down to the level of liner layer 312 so that a subsequently formed gate (not shown) will fully wrap around the active fin portion.

Furthermore, in various embodiments, design tools can be provided and configured to create the datasets used to pattern the semiconductor layers as described herein. For example, data sets can be created to generate photomasks used during lithography operations to pattern the layers for structures as described herein. Such design tools can include a collection of one or more modules and can also be comprised of hardware, software, or a combination thereof. Thus, for example, a tool can be a collection of one or more software modules, hardware modules, software/hardware modules, or any combination or permutation thereof, for performing the processing steps shown in FIGS. 2-3. In an exemplary embodiment, the design tool is configured to: form a set of replacement fins formed over a substrate, each of the set of replacement fins comprising a first section and a second section, the first section having a lower dopant centration than a dopant concentration of the second section; and form a liner layer between the first section from the second section.

As another example, a tool can be a computing device or other appliance on which software runs or in which hardware is implemented. As used herein, a module might be implemented utilizing any form of hardware, software, or a combination thereof. For example, one or more processors, controllers, ASICs, PLAs, logical components, software routines, or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

It is apparent that there has been provided an approach for forming a set of replacement fins in a semiconductor device. While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A semiconductor device comprising:
a set of replacement fins formed over a substrate, each of the set of replacement fins comprising a first section and a second section, the first section having a lower dopant centration than a dopant concentration of the second section; and
a liner layer between the first section and the second section.

2. The semiconductor device according to claim 1, the liner layer comprising carbon.

3. The semiconductor device according to claim 1, wherein the first section comprises a high mobility channel material.

4. The semiconductor device according to claim 3, the high-mobility channel material comprising one of: Si, and Si—Ge.

5. The semiconductor device according to claim 1, further comprising an oxide layer between each of set of replacement fins.

6. A method for forming a semiconductor device, the method comprising:
forming a set of replacement fins over a substrate, each of the set of replacement fins comprising a first section and a second section, the first section having a lower dopant centration than a dopant concentration of the second section; and
forming a liner layer between the first section from the second section.

7. The method according to claim 6, the forming the liner layer comprising implanting the set of replacement fins with carbon.

8. The method according to claim 6, the forming the liner layer comprising epitaxially forming the liner layer over the second section of each of the set of replacement fins.

9. The method according to claim 8, further comprising epitaxially forming the first section of each of set of replacement fins over the liner layer.

10. The method according to claim 6, the forming the set of replacement fins comprising:
patterning a set of fins from the substrate, wherein a hard mask is provided atop each of the set of fins;
forming an oxide material over the set of fins;
implanting the set of fins to form the second section;
removing the hard mask; and
epitaxially forming the first section atop the liner layer.

11. The method according to claim 10, further comprising recessing the oxide material to expose the first section.

12. The method according to claim 6, the forming the set of replacement fins comprising:
patterning a set of fins from the substrate, wherein a hard mask is formed atop each of the set of fins;
forming an oxide material over the set of fins;
removing the hard mask from atop each of the set of fins;
removing the set of fins;
epitaxially forming the second section over the substrate; and
epitaxially forming the first section over the second section.

13. The method according to claim 12, further comprising recessing the oxide material to expose the first section of each of the set of fins.

14. A method for forming a set of replacement fins in a semiconductor device, the method comprising:
forming a set of replacement fins over a substrate, each of the set of replacement fins comprising a first section and a second section, the first section having a lower dopant centration than a dopant concentration of the second section; and
forming a liner layer between the first section from the second section.

15. The method according to claim 14, the forming the liner layer comprising implanting each of the set of replacement fins with carbon.

16. The method according to claim 15, the forming the liner layer comprising epitaxially forming the liner layer over the second section of each of the set of replacement fins.

17. The method according to claim 16, further comprising epitaxially forming the first section of each of the set of replacement fins over the liner layer.

18. The method according to claim 14, the forming the set of replacement fins comprising:
patterning a set of fins from the substrate, wherein a hard mask is provided atop each of the set of fins;
forming an oxide material over the set of fins;
implanting the set of fins to form the second section;
removing the hard mask; and
epitaxially forming the first section atop the liner layer.

19. The method according to claim 14, the forming the set of replacement fins comprising:
patterning a set of fins from the substrate, wherein a hard mask is formed atop each of the set of fins;
forming an oxide material over the set of fins;
removing the hard mask from atop each of the set of fins;
removing the set of fins;
epitaxially forming the second section over the substrate; and
epitaxially forming the first section over the second section.

20. The method according to claim 19, further comprising recessing the oxide material to expose the first section.
